(19) United States
(12) Patent Application Publication
(10) Pub. No.: US 2008/0185670 A1
(43) Pub. Date: Aug. 7, 2008

(54) MAGNETIC RANDOM ACCESS MEMORY AND METHOD OF MANUFACTURING THE SAME

(76) Inventor: Takeshi KAJIYAMA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/870,164

(22) Filed: Oct. 10, 2007

(30) Foreign Application Priority Data
Oct. 11, 2006 (JP) 2006-277878

(51) Int. Cl. H01L 29/82; H01L 21/00

(52) U.S. Cl. 257/421; 438/3; 257/E29.323; 257/E21.001

(57) ABSTRACT

A magnetic random access memory includes an interlayer dielectric film having a contact hole, a contact formed in the contact hole, a first barrier metal film formed on an upper surface of the contact and buried in the contact hole, a magnetoresistive effect element having one terminal connected to the first barrier metal film, and including a fixed layer, a recording layer, and a nonmagnetic layer formed between the fixed layer and the recording layer, the magnetization directions in the fixed layer and the recording layer taking one of a parallel state and an antiparallel state in accordance with a direction of an electric current flowing between the fixed layer and the recording layer, a wiring connected to the other terminal of the magnetoresistive effect element, and a transistor connected to the magnetoresistive effect element via the contact and the first barrier metal film.

### CROSS-REFERENCE TO RELATED APPLICATIONS

This application is based upon and claims the benefit of priority from prior Japanese Patent Application No. 2006-277878, filed Oct. 11, 2006, the entire contents of which are incorporated herein by reference.

### BACKGROUND OF THE INVENTION

1. Field of the Invention

The present invention relates to a spin-injection magnetization-reversal-type magnetic random access memory (MRAM) and a method of manufacturing the same.

2. Description of the Related Art

A spin-injection magnetization-reversal-type magnetic random access memory (MRAM) has a cell structure different from that of a current-field-writing-type magnetic random access memory. That is, in the spin-injection magnetization-reversal-type MRAM, it is unnecessary to sandwich a magnetoresistive effect element between two wirings; a wiring is connected to one terminal of the magnetoresistive effect element, a switching element is connected to the other terminal of the magnetoresistive effect element, and an electric current flows through the magnetoresistive effect element during a write operation. In this structure, the cell area reduces when the magnetoresistive effect element is formed directly on a plug connecting to the switching element.

If, however, the magnetoresistive effect element is formed directly on the plug, the following problems arise.

First, during the implementation of this structure, the upper end portion of the plug is sometimes removed by etching for processing the magnetoresistive effect element. If this removal of the plug advances, the plug may be removed down to a portion below the magnetoresistive effect element. The removal of the plug like this varies a leakage magnetic field from the magnetoresistive effect element, thereby degrading the magnetic characteristics of the magnetoresistive effect element.

Also, when the plug is made of, e.g., W (tungsten), columnar crystals roughen the surface because the grain size of this material is large. In addition, this material having a large grain size may form a cavity in the center of the plug. Since the steps formed by this plug material degrade the flatness, the magnetoresistive effect element generates local magnetization and decreases the MR ratio. This degrades the magnetic characteristics of the magnetoresistive effect element.

Note that Jpn. Pat. Appln. KOKAI Publication No. 2005-340300 is prior art reference information related to the invention of this application.

### BRIEF SUMMARY OF THE INVENTION

A magnetic random access memory according to the first aspect of the present invention comprising an interlayer dielectric film having a contact hole, a contact formed in the contact hole, a first barrier metal film formed on an upper surface of the contact and buried in the contact hole, a magnetoresistive effect element having one terminal connected to the first barrier metal film, and including a fixed layer in which a magnetization direction is fixed, a recording layer in which a magnetization direction is reversible, and a nonmagnetic layer formed between the fixed layer and the recording layer, the magnetization directions in the fixed layer and the recording layer taking one of a parallel state and an antiparallel state in accordance with a direction of an electric current flowing between the fixed layer and the recording layer, a wiring connected to the other terminal of the magnetoresistive effect element, and a transistor connected to the magnetoresistive effect element via the contact and the first barrier metal film.

A magnetic random access memory manufacturing method according to the second aspect of the present invention comprising forming a transistor, forming an interlayer dielectric film on the transistor, forming a contact hole in the interlayer dielectric film, forming a contact in the contact hole, removing an upper portion of the contact to make an upper surface of the contact lower than an upper surface of the interlayer dielectric film, forming a trench, forming a first barrier metal film in the trench, forming a magnetoresistive effect element on the first barrier metal film and forming a wiring on the magnetoresistive effect element.

### BRIEF DESCRIPTION OF THE SEVERAL VIEWS OF THE DRAWING

FIG. 1 is a sectional view showing a magnetic random access memory according to the first embodiment of the present invention;

FIGS. 2 to 6 are sectional views showing steps in manufacturing the magnetic random access memory according to the first embodiment of the present invention;

FIG. 7 is a sectional view showing a magnetic random access memory according to the second embodiment of the present invention;

FIGS. 8 to 10 are sectional views showing steps in manufacturing the magnetic random access memory according to the second embodiment of the present invention; and

FIGS. 11 to 18 are sectional views showing magnetic random access memories according to the third embodiment of the present invention.

### DETAILED DESCRIPTION OF THE INVENTION

Embodiments of the present invention will be explained below with reference to the accompanying drawing. In the following explanation, the same reference numerals denote the same parts throughout the drawing.

### [1] Magnetic Random Access Memory

### [1-1] First Embodiment

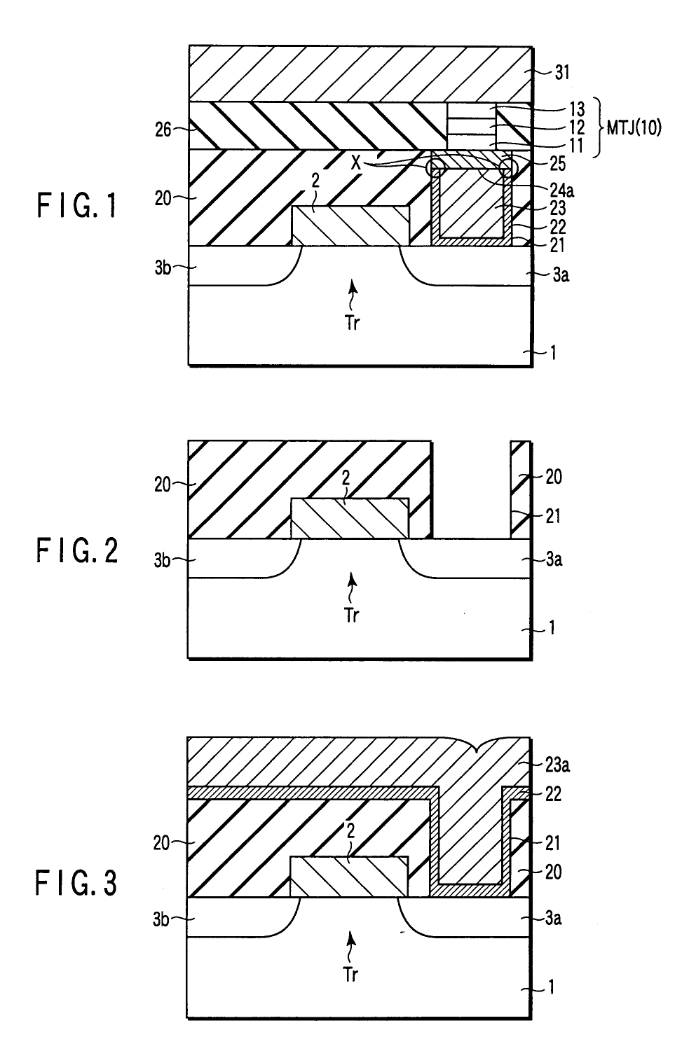

FIG. 1 is a sectional view of a magnetic random access memory according to the first embodiment of the present invention. The magnetic random access memory according to the first embodiment will be explained below.

As shown in FIG. 1, a gate electrode 2 is formed on a semiconductor substrate (silicon substrate) 1, and source/drain diffusion layers 3a and 3b are formed in the semiconductor substrate 1 on the two sides of the gate electrode 2, thereby forming a transistor (e.g., a MOS transistor) Tr that functions as a switching element.

A contact 23 made of, e.g., copper (Cu) or tungsten (W) is connected to the source/drain diffusion layer 3a of the transistor Tr. The contact 23 is formed in a contact hole 21 of an interlayer dielectric film 20. A barrier metal film 22 is formed on the side surfaces and bottom surface of the contact hole 21. The upper surfaces of portions X of the barrier metal film 22 on the side surfaces of the contact hole 21 are leveled with the upper surface of the contact 23. The upper surface of the contact 23 and the upper surfaces of the portions X of the barrier metal film 22 are positioned below the upper surface of the interlayer dielectric film 20. This forms a trench 24a in the upper portion of the contact hole 21.

A barrier metal film 25 is formed in the trench 24a. The barrier metal film 25 is formed on the upper surface of the contact 23 and the upper surfaces of the portions X of the barrier metal film 22, and buried in the contact hole 21. The upper surface of the barrier metal film 25 is leveled with the upper surface of the interlayer dielectric film 20. The side surfaces of the barrier metal film 25 are in contact with the side surfaces (the interlayer dielectric film 20) of the contact hole 21.

A magnetic tunnel junction (MTJ) element 10 as a magnetoresistive effect element is formed directly on the barrier metal film 25. The MTJ element 10 has a fixed layer (pinned layer) 11 in which the magnetization direction is fixed, a recording layer (free layer) 13 in which the magnetization direction is reversible, and a nonmagnetic layer 12 formed between the fixed layer 11 and recording layer 13. The fixed layer 11 of the MTJ element 10 is in contact with the barrier metal film 25. The recording layer 13 of the MTJ element 10 is in contact with a wiring 31. The area of the barrier metal film 25 is desirably larger than that of the MTJ element 10 in order to prevent the removal of the contact 23 when the MTJ element 10 is patterned.

As described above, the MTJ element 10 has one terminal connected in series with the transistor Tr via the contact 23 and barrier metal film 25, and the other terminal connected to the wiring 31. In this structure, a write current flows between the fixed layer 11 and recording layer 13 of the MTJ element 10.

FIGS. 2 to 6 are sectional views of steps in manufacturing the magnetic random access memory according to the first embodiment of the present invention. A method of manufacturing the magnetic random access memory according to the first embodiment will be explained below.

First, as shown in FIG. 2, a gate electrode 2 is formed on a semiconductor substrate 1 via a gate insulating film (not shown). Then, source/drain diffusion layers 3a and 3b are formed in the semiconductor substrate 1 on the two sides of the gate electrode 2 by ion implantation and annealing. In this manner, a transistor Tr is formed. An interlayer dielectric film 20 made of, e.g., a silicon oxide film is deposited to cover the transistor Tr. A contact hole 21 for exposing the source/drain diffusion layer 3a is formed by partially etching the interlayer dielectric film 20 by reactive ion etching (RIE) or the like.

Then, as shown in FIG. 3, a barrier metal film 22 made of, e.g., Ta, TaN, or TiN is formed in the contact hole 21 and on the interlayer dielectric film 20. A conductive film 23a made of, e.g., Cu or W is formed on the barrier metal film 22.

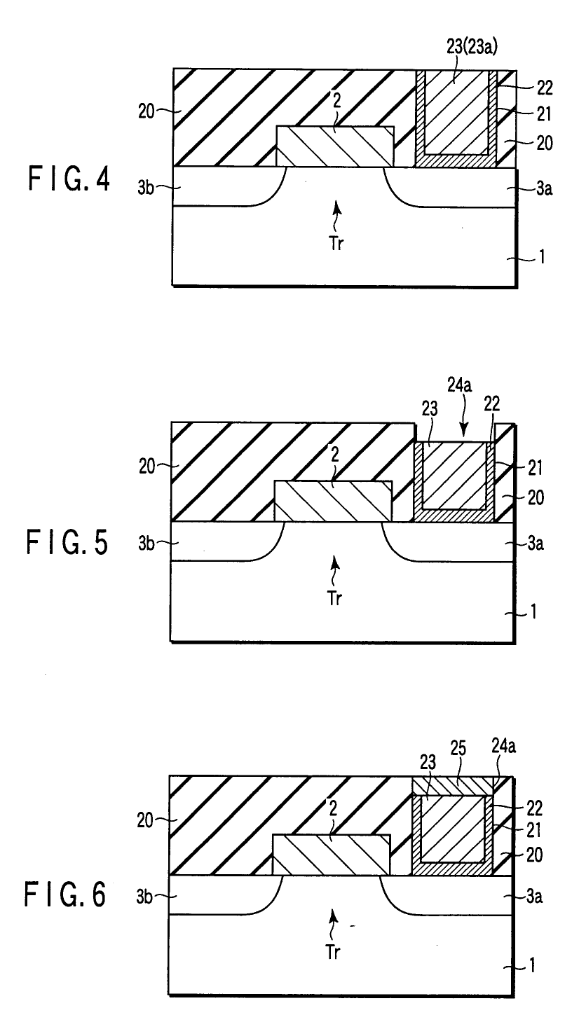

As shown in FIG. 4, the barrier metal film 22 and conductive film 23a are planarized by chemical mechanical polishing (CMP) or the like until the interlayer dielectric film 20 is exposed. In this way, a contact 23 and barrier metal film 22 are formed in the contact hole 21.

Subsequently, as shown in FIG. 5, the upper portions of the contact 23 and barrier metal film 22 are removed by, e.g., physical etching or wet etching using HCl. This makes the upper surfaces of the contact 23 and barrier metal film 22 lower than that of the interlayer dielectric film 20, thereby forming a trench 24a.

As shown in FIG. 6, a barrier metal film 25 made of, e.g., Ta, TaN, or TiN is deposited in the trench 24a and on the interlayer dielectric film 20. After that, the interlayer dielectric film 20 is exposed by planarizing the barrier metal film 25 by CMP or the like.

Then, as shown in FIG. 1, a fixed layer 11, nonmagnetic layer 12, and recording layer 13 are sequentially deposited and patterned on the barrier metal film 25 and interlayer dielectric film 20, thereby forming an MTJ element 10 on the barrier metal film 25. An interlayer dielectric film 26 is deposited to cover the MTJ element 10, and planarized until the MTJ element 10 is exposed. After that, a wiring 31 is formed on the MTJ element 10 and interlayer dielectric film 26.

### [1-2] Second Embodiment

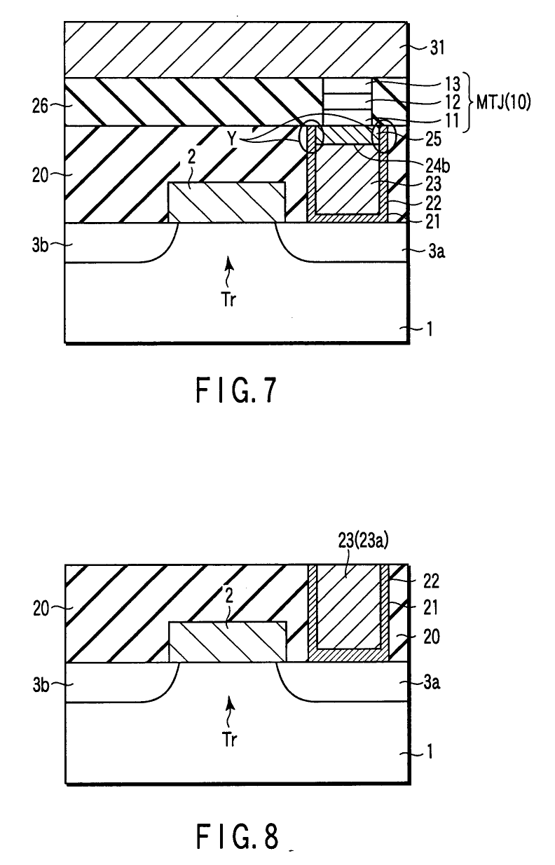

FIG. 7 is a sectional view of a magnetic random access memory according to the second embodiment of the present invention. The magnetic random access memory according to the second embodiment will be explained below. Note that in the second embodiment, the difference from the first embodiment will be mainly explained, and a repetitive explanation will be omitted.

As shown in FIG. 7, the difference of the second embodiment from the first embodiment is the structure of portions Y of a barrier metal film 22 on the side surfaces of a contact hole 21. That is, the upper surfaces of the portions Y of the barrier metal film 22 are positioned above the upper surface of a contact 23, and leveled with the upper surface of an interlayer dielectric film 20. Accordingly, a barrier metal film 25 is formed on only the upper surface of the contact 23, and is not formed on the upper surfaces of the portions Y of the barrier metal film 22. The side surfaces of the barrier metal film 25 are in contact with the side surfaces of the portions Y of the barrier metal film 22.

FIGS. 8 to 10 are sectional views of steps in manufacturing the magnetic random access memory according to the second embodiment of the present invention. A method of manufacturing the magnetic random access memory according to the second embodiment will be explained below.

First, as shown in FIG. 8, a contact 23 and barrier metal film 22 are formed in a contact hole 21 in the same manner as in the first embodiment.

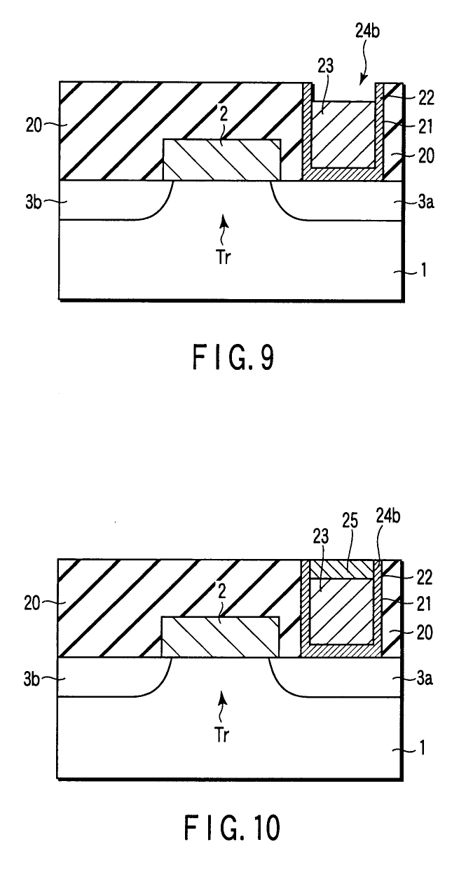

Then, as shown in FIG. 9, the upper portion of the contact 23 is removed by, e.g., physical etching or wet etching using HCl. This makes the upper surface of the contact 23 lower than that of an interlayer dielectric film 20, thereby forming a trench 24b. This etching is performed so as not to remove the barrier metal film 22.

As shown in FIG. 10, a barrier metal film 25 made of, e.g., Ta, TaN, or TiN is deposited in the trench 24b and on the interlayer dielectric film 20. Subsequently, the interlayer dielectric film 20 is exposed by planarizing the barrier metal film 25 by CMP or the like.

Then, as shown in FIG. 7, a fixed layer 11, nonmagnetic layer 12, and recording layer 13 are sequentially deposited and patterned on the barrier metal film 25 and interlayer dielectric film 20, thereby forming an MTJ element 10 on the barrier metal film 25. An interlayer dielectric film 26 is deposited to cover the MTJ element 10, and planarized until the MTJ element 10 is exposed. After that, a wiring 31 is formed on the MTJ element 10 and interlayer dielectric film 26.

### [1-3] Third Embodiment

The third embodiment is directed to modifications of the first and second embodiments. Note that the differences from the first and second embodiments will be mainly explained below, and a repetitive explanation will be omitted.

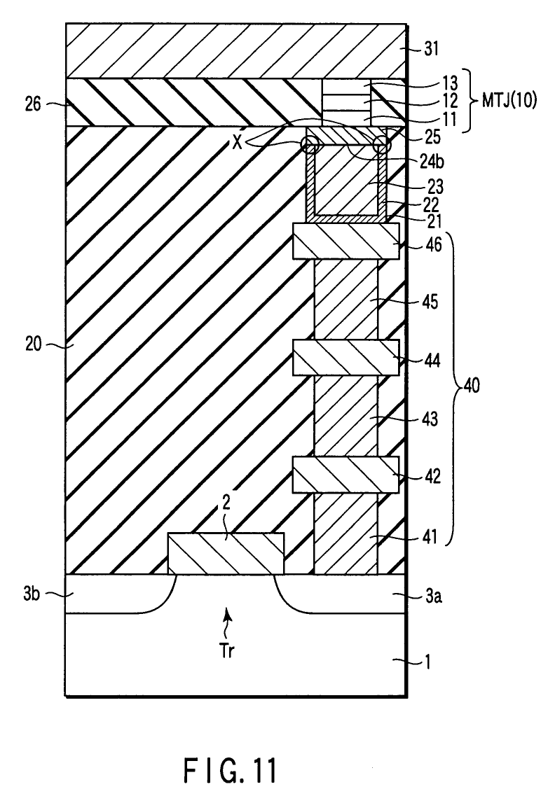

FIGS. 11 to 18 are sectional views of magnetic random access memories according to the third embodiment of the present invention. The magnetic random access memories according to the third embodiment will be explained below.

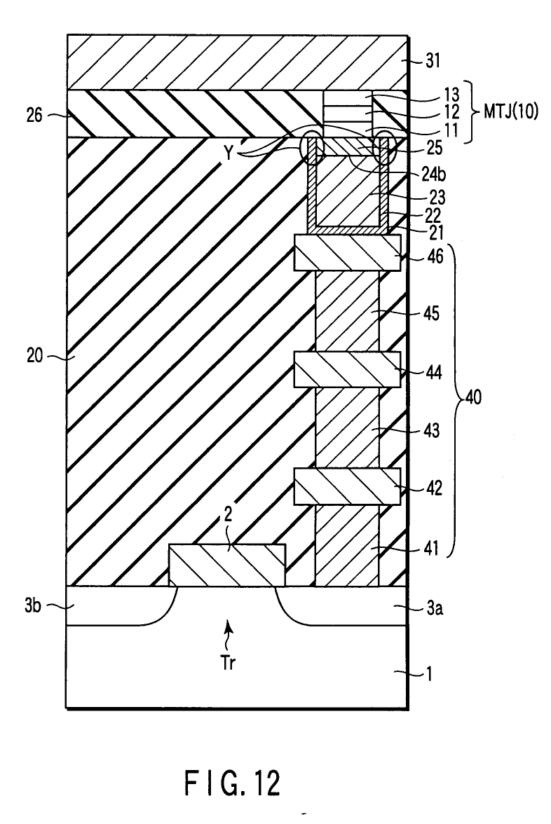

In modifications shown in FIGS. 11 and 12, a multilayered interconnecting portion 40 is formed below a contact 23 of the first and second embodiments. In the multilayered interconnecting portion 40, contacts 41, 43, and 45 and wirings 42, 44, and 46 are stacked. Note that the numbers of contacts and wirings to be stacked are not limited to those shown in FIGS. 11 and 12, and can be increased or decreased.

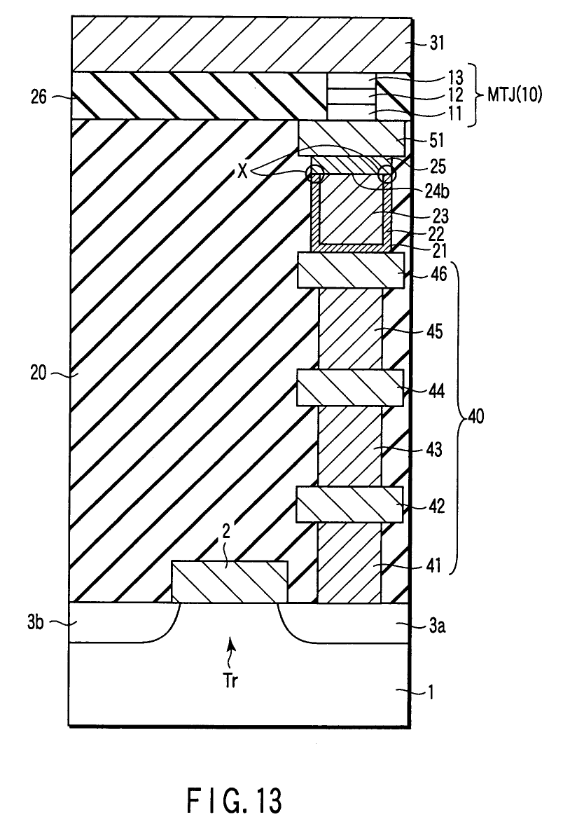

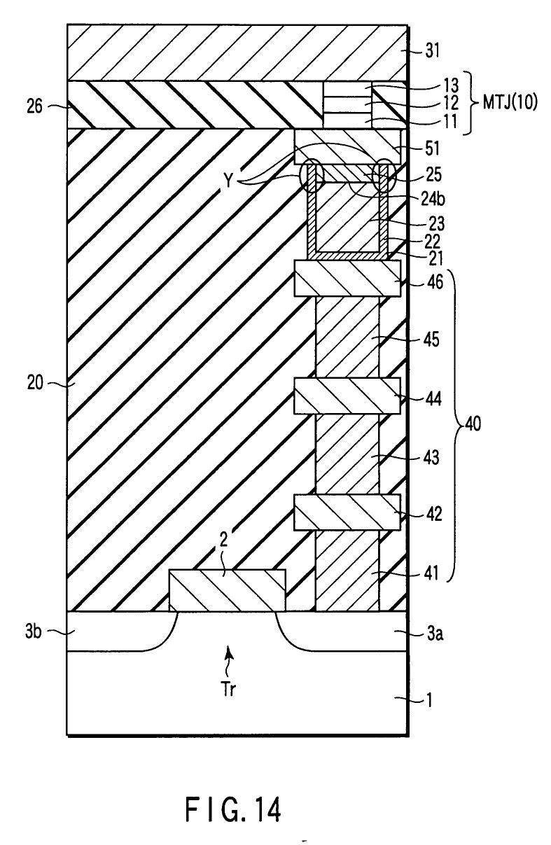

In modifications shown in FIGS. 13 and 14, an electrode layer 51 is formed between a barrier metal film 25 and MTJ element 10 in the structures shown in FIGS. 11 and 12.

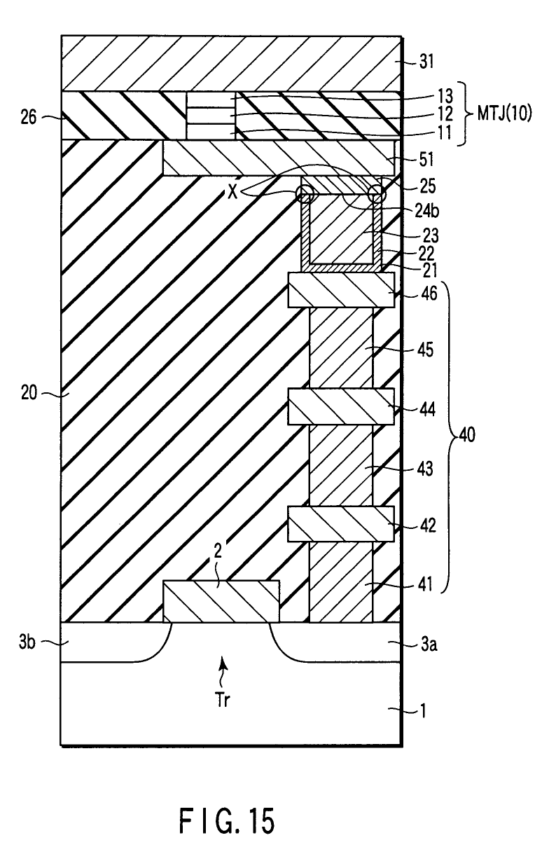

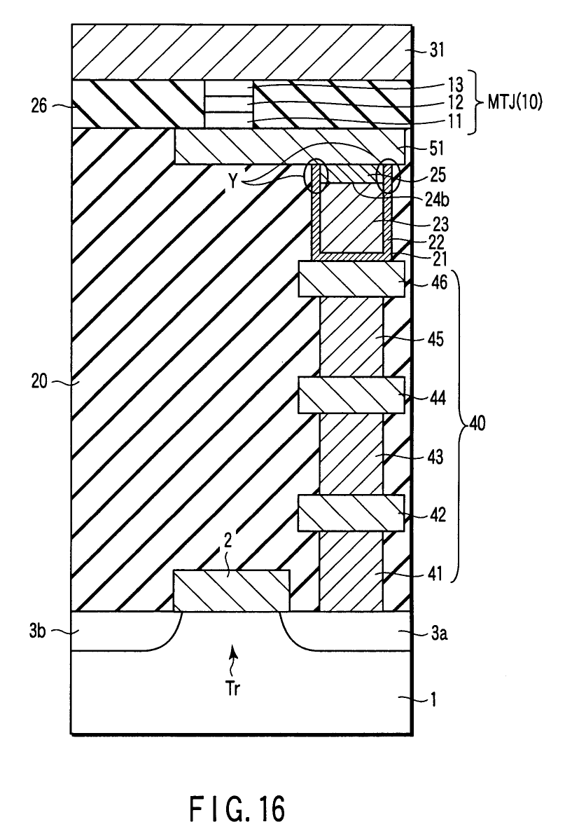

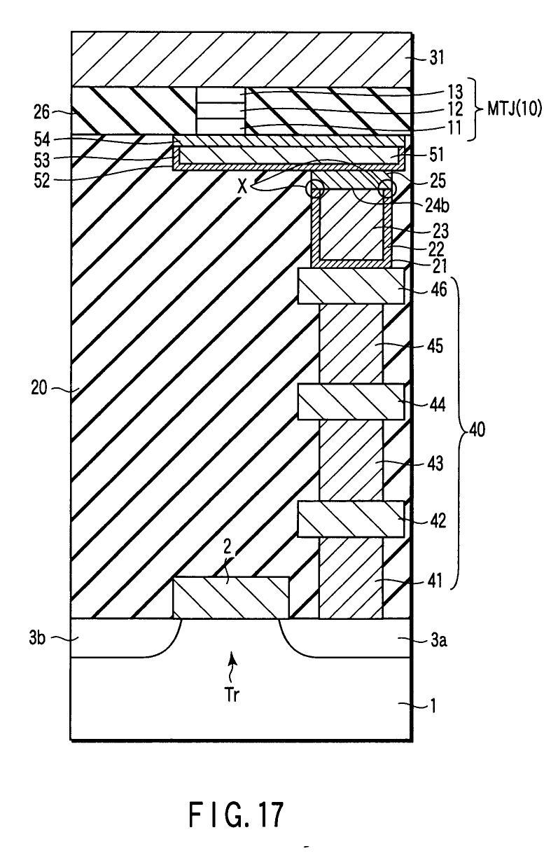

In modifications shown in FIGS. 15 and 16, the electrode layer 51 is extracted to a portion above a gate electrode 2, and the MTJ element 10 is formed on this extracted portion, in the structures shown in FIGS. 13 and 14.

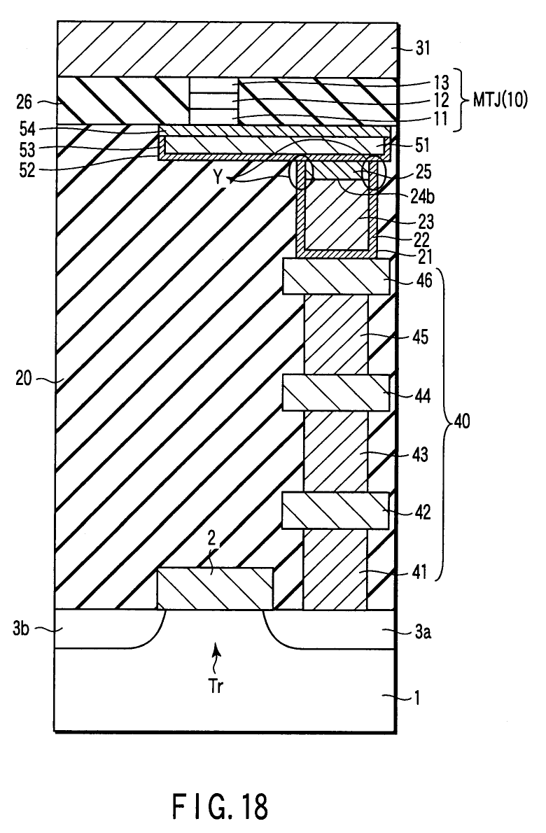

In modifications shown in FIGS. 17 and 18, the electrode layer 51 in the structures shown in FIGS. 13 and 14 has the same structure as the contact 23.

More specifically, as shown in FIG. 17, a barrier metal film 53 is formed on the side surfaces and bottom surface of a trench 52, the electrode layer 51 is formed on the barrier metal film 53, and a barrier metal film 54 is formed on the barrier metal film 53 and electrode layer 51. The upper surface of the barrier metal film 53 is leveled with that of the electrode layer 51. The barrier metal film 54 is buried in the trench 52. The side surfaces of the barrier metal film 54 are in contact with the side surfaces (an interlayer dielectric film 20) of the trench 52.

Also, as shown in FIG. 18, the barrier metal film 53 is formed on the side surfaces and bottom surface of the trench 52, the electrode layer 51 is formed on the barrier metal film 53, and the barrier metal film 54 is formed on the electrode layer 51. The upper surface of the barrier metal film 53 is leveled with that of the barrier metal film 54. The barrier metal film 54 is buried in the trench 52. The side surfaces of the barrier metal film 54 are in contact with the side surfaces of the barrier metal film 53.

In the third embodiment, the multilayered interconnecting portion 40 shown in FIGS. 13 to 18 may also be omitted. Also, as shown in FIGS. 17 and 18, the barrier metal films 53 and 54 may also be formed around the electrode layer 51 shown in FIGS. 13 and 14. The electrode layer 51 and barrier metal films 53 and 54 shown in FIG. 17 and the electrode layer 51 and barrier metal films 53 and 54 shown in FIG. 18 may also be switched.

In each of the above embodiments, a conductive layer such as an antiferromagnetic layer for fixing the magnetization direction in the fixed layer 11 may also be interposed between the fixed layer 11 and barrier metal film 25. Furthermore, a conductive layer such as a contact made of a hard mask or the like may also be interposed between the recording layer 13 and wiring 31.

In addition, the width of the contact 23 is larger than that of the MTJ element 10 in each embodiment, but the width of the contact 23 can also be smaller than that of the MTJ element 10. When a write operation is performed in the latter case, magnetization in the recording layer 13 reverses in only a portion where the electric current initially flows, and propagation occurs due to the current spin as the electric current keeps flowing after that. As a consequence, magnetization reverses in the whole of the recording layer 13. This achieves the effect that the current can be made low.

### [2] Barrier Metal Films

### [2-1] Materials

Examples of the materials of the barrier metal films 22, 25, 53, and 54 in the above embodiments are as follows.

(a) Ti

(b) Ta

(c) Compounds containing Ti (e.g., TiN, TiW, TiSiN, TiSiₓ, TiB₂, TiB, and TiC)

(d) Compounds containing Ta (e.g., TaB₂, TaB, TaC, TaN, Ta₄N₅, Ta₅N₆, and Ta₂N)

(e) Compounds containing Zr (e.g., ZrB₂, ZrB, ZrC, and ZrN)

(f) Compounds containing Hf (e.g., HfB, HfC, and HfN)

(g) Compounds containing V (e.g., VB₂, VB, VC, and VN)

(h) Compounds containing Nb (e.g., NbB₂, NbB, NbC, and NbN)

(i) Compounds containing Cr (e.g., CrB₂, CrB, Cr₂B, Cr₃C₂, Cr₂N, and CrN)

(j) Compounds containing Mo (e.g., Mo₂B₃, MoB₂, MoB, Mo₂B, MoₓC_{y}, Mo₂C, and MoN)

(k) Compounds containing W (e.g., WₓB_{y}, W₂B₅, WₓC_{y}, WC, W₂C, WₓN_{y}, and WN)

Of materials (a) to (k) above, it is desirable to use Ta, a Ta-containing compound, Ti, or a Ti-containing compound as the material of the barrier metal films, 22, 25, 53, and 54, from the viewpoint of the convenience of use.

Note that the material of the barrier metal film 25 may be the same as or different from that of the barrier metal film 22. Note also that the material of the barrier metal film 53 may be the same as or different from that of the barrier metal film 54. When these barrier metal films are made of the same material, they can be processed at the same time during the manufacturing process.

### [2-2] Stacked Film

In the above embodiments, each of the barrier metal films 22, 25, 53, and 54 may be a single-layer film or a stacked film. A stacked film is made of a combination of materials (a) to (k) described above, e.g., TaN/Ta or TiN/TiSiₓ.

Note that the stacked structure of the barrier metal film 25 may be the same as or different from that of the barrier metal film 22. Note also that the stacked structure of the barrier metal film 53 may be the same as or different from that of the barrier metal film 54. When these barrier metal films have the same stacked structure, they can be processed at the same time during the manufacturing process.

### [2-3] Film Thickness

In the above embodiments, the film thicknesses of the barrier metal films 22, 25, 53, and 54 may be the same or different. However, the film thickness of the barrier metal film 25 is desirably larger than that of the barrier metal film 22, in order to protect the Cu contact 23 when the MTJ element 10 is processed, or absorb the roughness of the upper surface of the W contact 23. Likewise, the film thickness of the barrier metal film 53 is desirably larger than that of the barrier metal film 54.

### [3] MTJ Element

### [3-1] Materials

Examples of the materials of the MTJ element MT are as follows.

Favorable examples of the materials of the fixed layer 11 and recording layer 13 are Fe, Co, Ni, and their alloys, magnetite having a high spin polarization ratio, oxides such as CrO₂ and RXMnO_{3-y} (R: rare earth element; X: Ca, Ba, and Sr), and Heusler alloys such as NiMnSb and PtMnSb. These magnetic materials can more or less contain nonmagnetic elements such as Ag, Cu, Au, Al, Mg, Si, Bi, Ta, B, C, O, N, Pd, Pt, Zr, Ir, W, Mo, and Nb, provided that the materials do not lose ferromagnetism.

As the material of the nonmagnetic layer 12, it is possible to use various dielectrics such as Al₂O₃, SiO₂, MgO, AlN, Bi₂O₃, MgF₂, CaF₂, SrTiO₂, and AlLaO₃. These dielectrics may have oxygen, nitrogen, and fluorine deficiencies.

An antiferromagnetic layer for fixing the magnetization direction in the fixed layer 11 can also be formed on the side of the fixed layer 11 away from the nonmagnetic layer 12. As the material of this antiferromagnetic layer, it is favorable to use, e.g., Fe—Mn, Pt—Mn, Pt—Cr—Mn, Ni—Mn, Ir—Mn, NiO, or Fe₂O₃.

### [3-2] Parallel Magnetization Type/Perpendicular

Magnetization Type

The magnetization directions in the fixed layer 11 and recording layer 13 of the MTJ element 10 can be parallel to the film surface (parallel magnetization type) or perpendicular to the film surface (perpendicular magnetization type).

Examples of a perpendicular magnetic material are as follows.

First, a magnetic material having a high coercive force to be used as the perpendicular magnetic material of the fixed layer 11 and recording layer 13 is made of a material having a high magnetic anisotropic energy density of 1×10⁶ erg/cc or more. Examples of the material will be explained below.

### Example 1

“A material made of an alloy containing at least one of iron (Fe), cobalt (Co), and nickel (Ni) and at least one of chromium (Cr), platinum (Pt), and palladium (Pd)”

Examples of an ordered alloy are Fe(50)Pt(50), Fe(50)Pd(50), and Co(50)Pt(50). Examples of a random alloy are a CoCr alloy, CoPt alloy, CoCrPt alloy, CoCrPtTa alloy, and CoCrNb alloy.

### Example 2

“A material having a structure in which at least one of Fe, Co, and Ni or an alloy containing one of these elements and one of Pd and Pt or an alloy containing one of these elements are alternately stacked”

Examples are a Co/Pt artificial lattice, Co/Pd artificial lattice, and CoCr/Pt artificial lattice. When the Co/Pt artificial lattice or Co/Pd artificial lattice is used, a high resistance change ratio (MR ratio) of about 40% can be achieved.

### Example 3

“An amorphous alloy containing at least one rare earth metal such as terbium (Tb), dysprosium (Dy), or gadolinium (Gd), and at least one transition metal”

Examples are TbFe, TbCo, TbFeCo, DyTbFeCo, and GdTbCo.

The recording layer 13 can be made of the magnetic material having a high coercive force as described above, and can also be made of a magnetic material having a magnetic anisotropic energy density lower than that of the magnetic material having a high coercive force as described above, by adjusting the composition ratio, adding an impurity, or adjusting the thickness. Examples of the material will be explained below.

### Example 1

“A material obtained by adding an impurity to an alloy containing at least one of Fe, Co, and Ni and at least one of Cr, Pt, and Pd”

An example of an ordered alloy is a material obtained by decreasing the magnetic anisotropic energy density by adding an impurity such as Cu, Cr, or Ag to Fe(50)Pt(50), Fe(50)Pd(50), or Co(50)Pt(50). An example of a random alloy is a material obtained by decreasing the magnetic anisotropic energy density by increasing the ratio of a nonmagnetic element in a CoCr alloy, CoPt alloy, CoCrPt alloy, CoCrPtTa alloy, or CoCrNb alloy.

### Example 2

“A material having a structure in which at least one of Fe, Co, and Ni or an alloy containing one of these elements and one of Pd and Pt or an alloy containing one of these elements are alternately stacked, and the thickness of the layer made of the former element or alloy or the thickness of the layer made of the latter element or alloy is adjusted”

The thickness of the layer made of at least one of Fe, Co, and Ni or an alloy containing one of these elements has an optimum value, and the thickness of the layer made of one of Pd and Pt or an alloy containing one of these elements has an optimum value. As the thicknesses deviate from these optimum values, the magnetic anisotropic energy density decreases.

### Example 3

“A material obtained by adjusting the composition ratio of an amorphous alloy containing at least one rare earth metal such as terbium (Tb), dysprosium (Dy), or gadolinium (Gd) and at least one transition metal”

An example is a material obtained by decreasing the magnetic anisotropic energy density by adjusting the composition ratio of an amorphous alloy such as TbFe, TbCo, TbFeCo, DyTbFeCo, or GdTbCo.

### [3-3] Planar Shape

The planar shape of the MTJ element 10 can be variously changed. Examples are a rectangle, square, ellipse, circle, hexagon, rhomb, parallelogram, cross, and bean (recessed shape).

In the parallel-magnetization-type MTJ element 10, the magnetization direction has shape anisotropy. Therefore, when the dimension in the widthwise direction (hard magnetization axis direction) of the MTJ element 10 is F (minimum processing dimension), the dimension in the longitudinal direction (easy magnetization axis direction) of the MTJ element 10 is desirably about 2F.

The perpendicular-magnetization-type MTJ element 10 can have any of the above shapes because the magnetization direction is independent of the shape.

### [3-4] Tunnel Junction Structure

The MTJ element 10 can have a single tunnel junction (single-junction) structure or double tunnel junction (double-junction) structure.

As shown in FIG. 1 and the like, the MTJ element 10 having the single tunnel junction structure has the fixed layer 11, the recording layer 13, and the nonmagnetic layer 12 formed between the fixed layer 11 and recording layer 13. That is, the MTJ element 10 has one nonmagnetic layer.

The MTJ element 10 having the double tunnel junction structure has a first fixed layer, a second fixed layer, a recording layer formed between the first and second fixed layers, a first nonmagnetic layer formed between the first fixed layer and recording layer, and a second nonmagnetic layer formed between the second fixed layer and recording layer. That is, the MTJ element 10 has two nonmagnetic layers.

When the same external bias is applied, the magnetoresistive (MR) ratio (the resistance change ratio of state “1” to state “0”) decreases less in the double tunnel junction structure than in the single tunnel junction structure, so the former can operate with a higher bias than the latter. That is, the double tunnel junction structure is advantageous in reading information from a cell.

### [4] Write Operation

In the magnetic random access memory according to the embodiment of the present invention, data is written by using spin-injection magnetization reversal. In the MTJ element 10, therefore, the magnetization directions in the fixed layer 11 and recording layer 13 become parallel or antiparallel in accordance with the direction of an electric current I flowing between the fixed layer 11 and recording layer 13. Details are as follows.

When writing data “1”, the electric current I is supplied in the direction from the fixed layer 11 to the recording layer 13 of the MTJ element 10. That is, electrons e are injected from the recording layer 13 into the fixed layer 11. This makes the magnetization directions in the fixed layer 11 and recording layer 13 opposite, i.e., antiparallel. A high-resistance state Rap like this is defined as data “1”.

On the other hand, when writing data “0”, the electric current I is supplied in the direction from the recording layer 13 to the fixed layer 11 of the MTJ element 10. That is, the electrons e are injected from the fixed layer 11 into the recording layer 13. This makes the magnetization directions in the fixed layer 11 and recording layer 13 the same, i.e., parallel. A low-resistance state Rp like this is defined as data “0”.

### [5] Read Operation

A read operation of the magnetic random access memory according to the embodiment of the present invention uses the magnetoresistive effect.

The transistor Tr connecting to the MTJ element 10 of a selected cell is turned on to supply a read current from, e.g., the wiring 31 to the transistor Tr through the MTJ element 10. Whether the data is “1” or “0” is determined by the resistance of the MTJ element 10 read on the basis of this read current.

Note that the read operation can be performed by reading the current by applying a constant voltage, or by reading the voltage by applying a constant current.

### [6] Effects

The embodiment of the present invention described above forms the barrier metal film 25 made of Ta, TaN, or TiN on the contact 23 made of Cu or W, and forms the MTJ element 10 on the barrier metal film 25. That is, the barrier metal film 25 exists on the contact 23 when the MTJ element 10 is patterned.

Even when the contact 23 is made of Cu that is easy to remove, therefore, the barrier metal film 25 protects the contact 23 from being etched away during patterning. This makes it possible to prevent etching from reducing the amount of the Cu material around the MTJ element 10, or prevent etching from advancing to a portion below the MTJ element 10 if etching has an isotropic component. As a consequence, it is possible to suppress degradation of the magnetic characteristics of the MTJ element 10 unlike in the conventional method.

In addition, even when the contact 23 is made of W that easily forms columnar crystals and readily roughens the upper surface, the steps on the upper surface of the W contact 23 can be absorbed by forming the barrier metal film 25 on the contact 23. Accordingly, the flatness of the undercoat of the MTJ element 10 can be held. This makes it possible to suppress degradation of the magnetic characteristics of the MTJ element 10 unlike in the conventional method.

And, unevenness at the upper surface of contact 23 may appear by grain growth and migration. But, unevenness at the upper surface of contact 23 can be controlled in case of CMP by using barrier metal material (in such cases as Ta, TaN, TiN and TiSiN) whose grain diameter is small.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic random access memory comprising:
an interlayer dielectric film having a contact hole;
a contact formed in the contact hole;
a first barrier metal film formed on an upper surface of the contact and buried in the contact hole;
a magnetoresistive effect element having one terminal connected to the first barrier metal film, and including a fixed layer in which a magnetization direction is fixed, a recording layer in which a magnetization direction is reversible, and a nonmagnetic layer formed between the fixed layer and the recording layer, the magnetization directions in the fixed layer and the recording layer taking one of a parallel state and an antiparallel state in accordance with a direction of an electric current flowing between the fixed layer and the recording layer;
a wiring connected to the other terminal of the magnetoresistive effect element; and
a transistor connected to the magnetoresistive effect element via the contact and the first barrier metal film.

2. The memory according to claim 1, wherein a material of the contact is one of copper and tungsten.

3. The memory according to claim 1, wherein a material of the first barrier metal film is one of Ta and a compound containing Ta.

4. The memory according to claim 1, wherein a material of the first barrier metal film is one of Ti and a compound containing Ti.

5. The memory according to claim 1, wherein an area of the first barrier metal film is larger than an area of the magnetoresistive effect element.

6. The memory according to claim 1, further comprising a second barrier metal film having a first portion formed on a side surface of the contact hole, and a second portion formed on a bottom surface of the contact hole, an upper surface of the first portion being positioned below an upper surface of the interlayer dielectric film.

7. The memory according to claim 6, wherein the first barrier metal film is formed on the upper surface of the first portion and the upper surface of the contact.

8. The memory according to claim 6, wherein a side surface of the first barrier metal film is in contact with the side surface of the contact hole.

9. The memory according to claim 6, wherein a material of the first barrier metal film is the same as a material of the second barrier metal film.

10. The memory according to claim 6, wherein a film thickness of the first barrier metal film is larger than a film thickness of the second barrier metal film.

11. The memory according to claim 1, further comprising a second barrier metal film having a first portion formed on a side surface of the contact hole, and a second portion formed on a bottom surface of the contact hole, an upper surface of the first portion being leveled with an upper surface of the interlayer dielectric film.

12. The memory according to claim 11, wherein a side surface of the first barrier metal film is in contact with the first portion.

13. The memory according to claim 11, wherein a material of the first barrier metal film is the same as a material of the second barrier metal film.

14. The memory according to claim 11, wherein a film thickness of the first barrier metal film is larger than a film thickness of the second barrier metal film.

15. A magnetic random access memory manufacturing method comprising:
forming a transistor;
forming an interlayer dielectric film on the transistor;
forming a contact hole in the interlayer dielectric film;
forming a contact in the contact hole;
removing an upper portion of the contact to make an upper surface of the contact lower than an upper surface of the interlayer dielectric film, forming a trench;
forming a first barrier metal film in the trench;
forming a magnetoresistive effect element on the first barrier metal film; and
forming a wiring on the magnetoresistive effect element.

16. The method according to claim 15, further comprising:
forming a second barrier metal film in the contact hole before forming the contact; and
removing an upper portion of the second barrier metal film as well when removing the upper portion of the contact.

17. The method according to claim 16, wherein an upper surface of a portion, which is formed on a side surface of the contact hole, of the second barrier metal film is positioned below an upper surface of the interlayer dielectric film.

18. The method according to claim 15, which further comprises forming a second barrier metal film in the contact hole before forming the contact, and in which the second barrier metal film is not removed when the upper portion of the contact is removed.

19. The method according to claim 18, wherein an upper surface of a portion, which is formed on a side surface of the contact hole, of the second barrier metal film is leveled with an upper surface of the interlayer dielectric film.

20. The method according to claim 15, wherein the magnetoresistive effect element includes a fixed layer in which a magnetization direction is fixed, a recording layer in which a magnetization direction is reversible, and a nonmagnetic layer formed between the fixed layer and the recording layer, the magnetization directions in the fixed layer and the recording layer taking one of a parallel state and an antiparallel state in accordance with a direction of an electric current flowing between the fixed layer and the recording layer.
